(19) United States
(12) Patent Application Publication
(10) Pub. No.: US 2025/0359065 A1
(43) Pub. Date: Nov. 20, 2025

(54) VERTICAL FERROELECTRIC FIELD EFFECT TRANSISTOR WITH EPITAXIAL CHANNEL

(71) Applicant: International Business Machines Corporation, Armonk, NY (US)

(72) Inventors: Nanbo Gong, White Plains, NY (US); Takashi Ando, Eastchester, NY (US); Guy M. Cohen, Ossining, NY (US)

(21) Appl. No.: 18/669,493

(22) Filed: May 20, 2024

(51) Int. Cl. H10B 51/20; H10B 51/30

(52) U.S. Cl. CPC H10B 51/20; H10B 51/30

(57) ABSTRACT

A vertical ferroelectric field effect transistor includes a source, a drain, and a channel in a channel opening vertically connecting the source and the drain. On either side of the channel are an alternating stack of a plurality of insulator layers and a plurality of metal electrodes. A cover insulator is over the alternating stack while the source is over and in contact with a top surface of the cover insulator. A ferroelectric layer is between and in contact with each of the plurality of metal electrodes and a portion of the channel sidewalls.

### BACKGROUND

The present invention relates generally to the electrical, electronic and computer arts and, more particularly, to techniques for forming vertical ferroelectric field effect transistors (FeFETs) and the like.

A ferroelectric field effect transistor is a non-volatile random-access memory that stores binary data as an electric polarity in a dipole in a ferroelectric material. Depending on the polarity of the electric field applied to the ferroelectric material, the dipole moment of the ferroelectric material is programmed in an “up” or “down” orientation. The orientation can be detected by measuring the current flowing through a semiconductor channel adjacent to the ferroelectric material. To determine on and off, the threshold voltage (Vt) is used, and if V>Vt, the FeFET is on, and if V less than Vt, the FeFET is off. The Vt can be high (Vt1), or low (Vt2), where Vt2 is less than Vt1. The difference of Vt1−Vt2 is known as the memory window (MW).

### BRIEF SUMMARY

Principles of the invention provide techniques for forming a vertical ferroelectric field effect transistor with an epitaxial single crystalline channel and using a replacement metal electrode technique. In one aspect, an exemplary vertical ferroelectric field effect transistor includes a source, a drain, and a channel in a channel opening vertically connecting the source and the drain. On either side of the channel are an alternating stack of a plurality of insulator layers and a plurality of metal electrodes. A cover insulator is over the alternating stack while the source is over and in contact with a top surface of the cover insulator. A ferroelectric layer is between and in contact with each of the plurality of metal electrodes and a portion of the channel sidewalls.

In another aspect, another example vertical ferroelectric field effect transistor includes a source, a drain and a channel in a channel opening vertically between the source and the drain. The channel includes a single crystalline semiconductor filling the entire channel opening. An alternating stack of a plurality of insulator layers and a plurality of metal electrodes are on either side of the channel. A ferroelectric layer is between and in contact with each of the plurality of metal electrodes 245 and a portion of the channel sidewalls. The ferroelectric layer has a rectangular shape and is lattice matched to the channel.

In still a further aspect, an exemplary method of forming a vertical ferroelectric field effect transistor includes providing a semiconductor substrate having a first doping, doping the substrate to form a source on the substrate, the source having a second doping opposite the first doping, forming alternating layers of an insulator and a sacrificial material having a stepped profile end, forming a channel opening through the alternating layers to expose the source, forming a single crystalline semiconductor channel in the channel opening, forming a drain on the channel opposite the source, forming a vertical cavity through the insulator to expose a portion of the sacrificial material at the stepped profile end, removing the sacrificial material to form a horizontal cavity in communication with the vertical cavity and to expose a portion of the channel sidewall, forming a ferroelectric layer having a rectangular shape on the channel sidewall, and forming a metal electrode in the vertical cavity and the horizontal cavity and in contact with the ferroelectric layer.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Epitaxial single crystalline channel provides low interface trap density (Dit) and improved interface quality which enhances device performance, such as mobility, and improves endurance;
Epitaxial single crystalline channel can further enhance the memory window by improved control of polarization orientation alignments; Vertical configuration provides a high density storage solution;
The sacrificial material replacement by a doped ferroelectric layer and metal electrode provides thermal budget control of the gate stack module and allows for better memory window and threshold voltage adjustment.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 depicts an exemplary process flow for manufacturing a ferroelectric field effect transistor in accordance with aspects of the invention;

FIGS. 2 through 8A and 8B depict cross-sections of steps in an exemplary process flow for manufacturing ferroelectric field effect transistors in accordance with aspects of the invention; and

FIGS. 9A and 9B each depict a cross-section of an exemplary ferroelectric field effect transistors connected to interconnects in accordance with aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

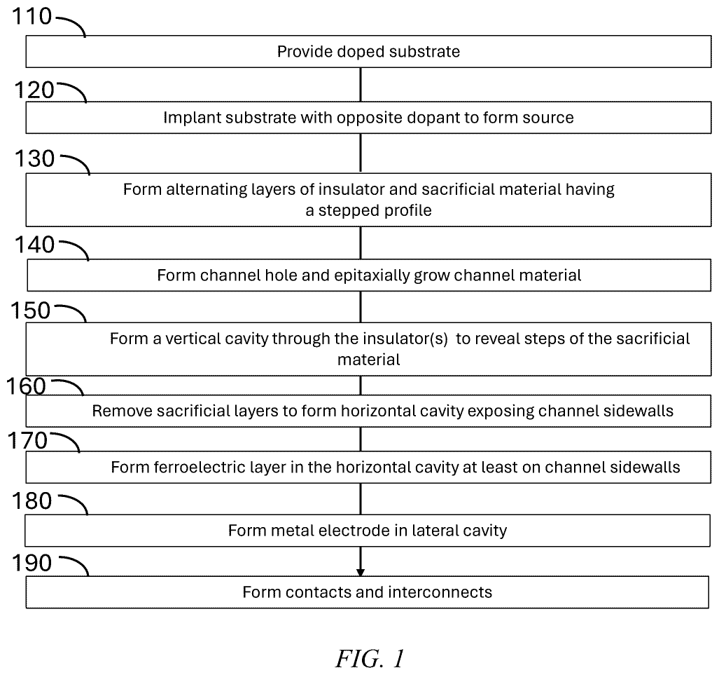

Aspects of invention provide a method of making a vertical FeFET having an epitaxial channel and a ferroelectric layer and metal electrode formed by a replacement process. FIG. 1 depicts an exemplary method of making an exemplary ferroelectric field effect transistor in accordance with aspects of the invention. Step 110 starts with providing a doped semiconductor substrate, for example and not by limitation, the semiconductor may be P-doped bulk silicon.

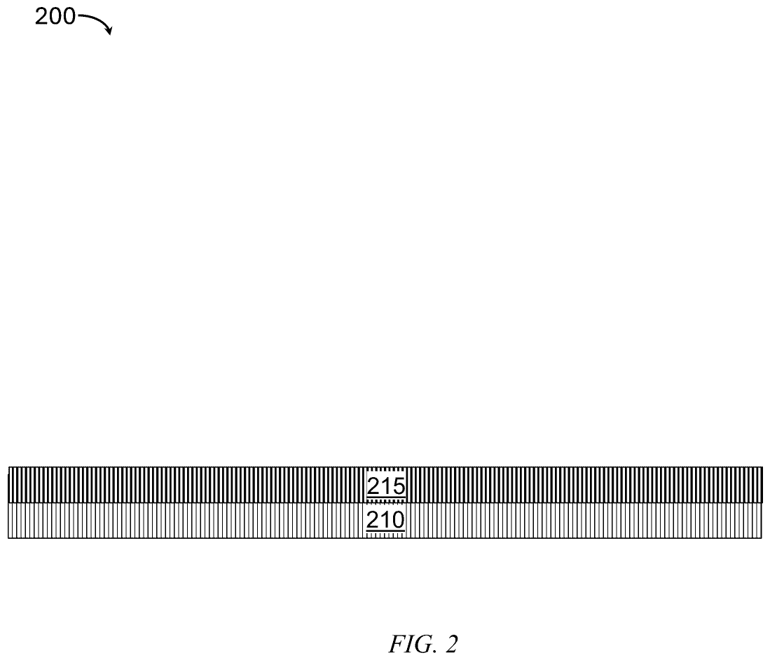

In step 120 and referring to FIG. 2, the substrate 210 is doped to with an opposite polarity dopant to form a source 215 layer on the substrate 210. For example, and not by limitation, the semiconductor may be N-doped bulk silicon.

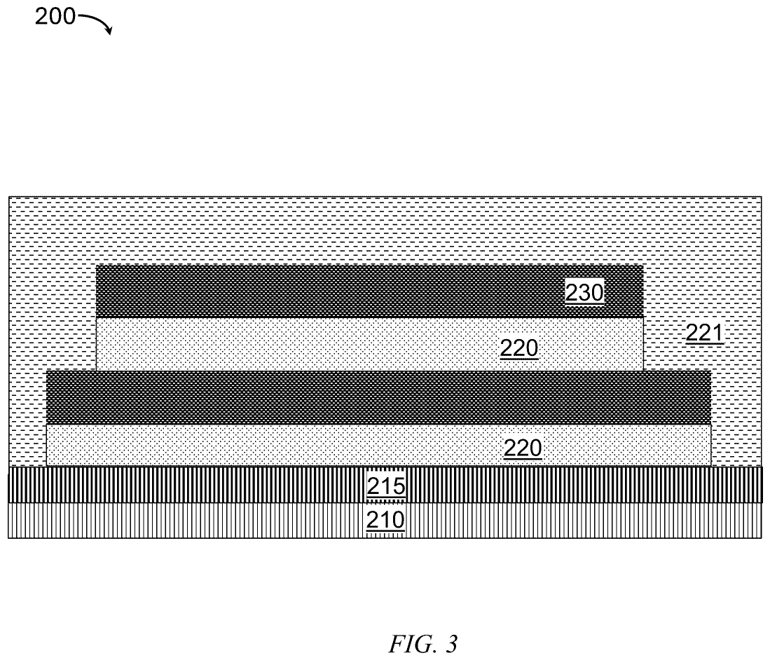

Next, in step 130 and referring to FIG. 3, alternating layers of an insulator 220 and sacrificial material 230 are deposited and patterned to form stepped pairs of insulator 220 and sacrificial material 230. The stepped structure is then encased in a cover insulator 221. The insulator 220 can be any dielectric film. The sacrificial material 230 can be any film which can be removed selectively with respect to the insulator 220 and, importantly, is not a material which upon which epitaxial semiconductors can be readily grown. An exemplary insulator 220 can be a silicon oxide and an exemplary sacrificial material 230 can be a silicon nitride, however, polysilicon, SiGe or similar materials would not be sacrificial materials 230 because epitaxial films can be readily grown on them. Cover insulator 221 can be any dielectric film and can be more than one film.

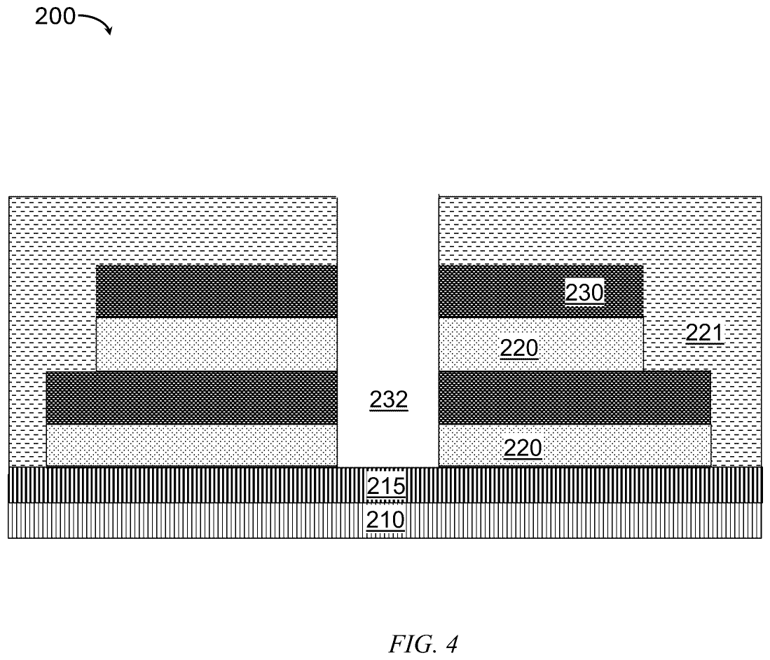

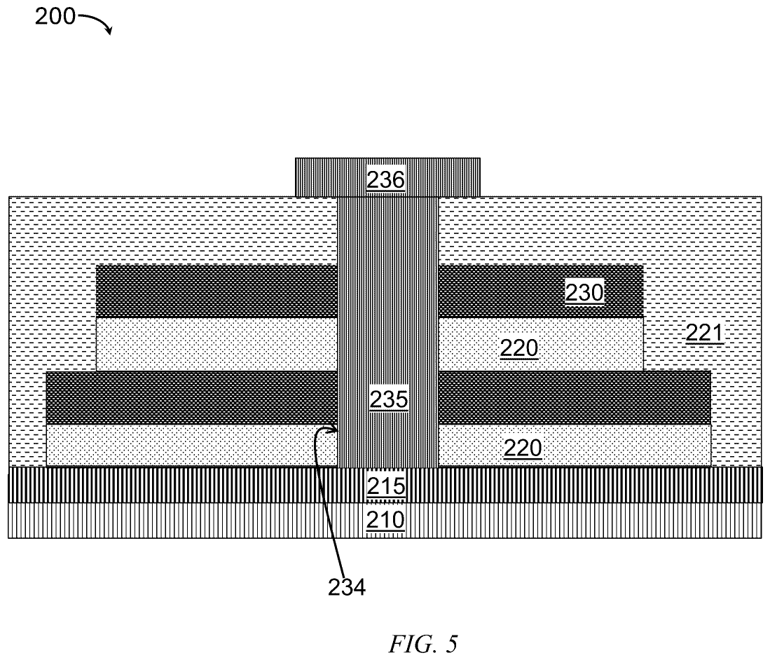

Continuing with FIG. 1, in step 140 and referring to FIG. 4, a channel opening 232 is lithographically formed and etched through the alternating layers of insulator 220 and sacrificial material 230 and the cover insulator 221 to expose the source 215 layer. Referring to FIG. 5 a channel 235 of semiconductor material is epitaxially formed from the source 215 up to fill the entire opening and create a pad on top of a portion of the cover insulator 221. The pad will act as the drain 236 of the transistor. Each of the drain 236 and source 215 being doped to reduce external resistance. The channel 235 semiconductor is a single crystalline semiconductor. For example, the channel 235 semiconductor may be silicon, silicon germanium or a III-V compound.

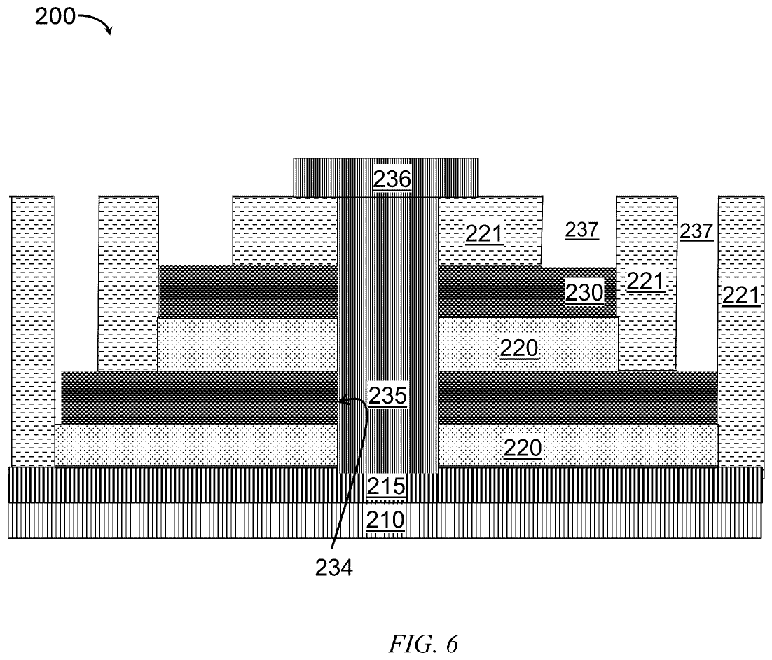

In step 150, vertical cavities 237 are lithographically formed and etched through the various layers to land upon a top surface of the sacrificial material 230 of one more of the steps of alternating layer pairs (see FIG. 6).

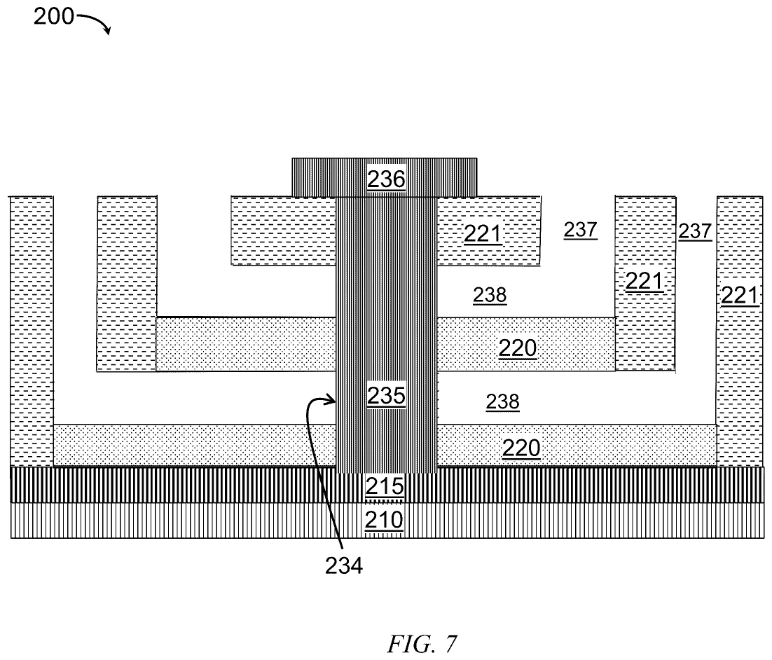

With a portion of the sacrificial material 230 exposed, step 160 selectively removes the sacrificial material 230 relative to the insulator 220 to form a plurality of horizontal cavities 238 that expose different portions of the channel 235 sidewall (see FIG. 7). The selective etching can be done either by wet etching or reactive ion etching, depending on the choice of materials. For example, when SiN is used for the sacrificial material 230 and SiO2 is used for the insulator 220, hot phosphoric acid (H3PO4) etching can be used. Advantageously, the selective etch can be isotropic.

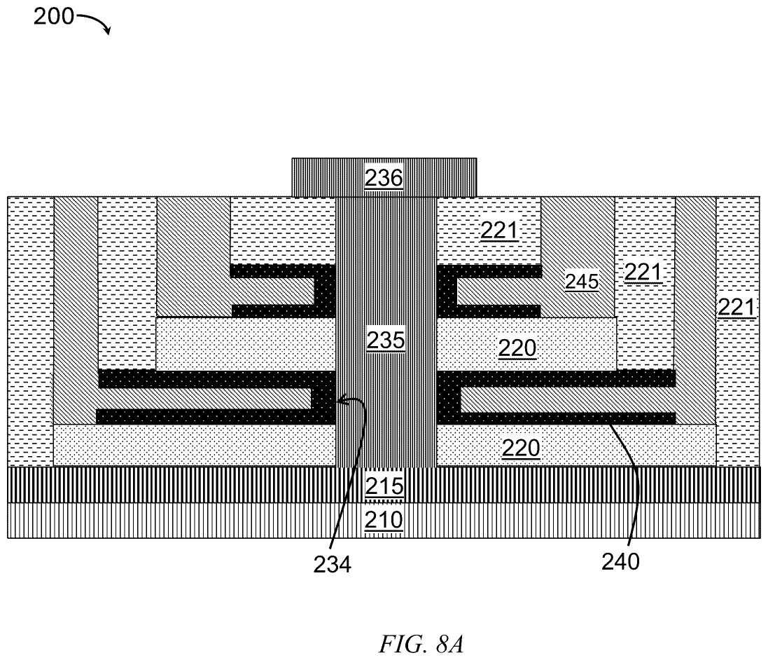

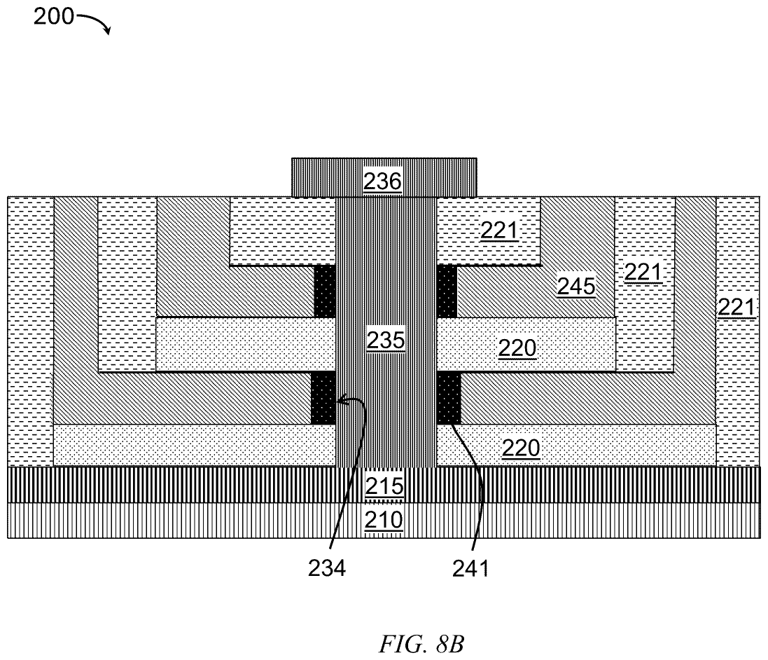

In step 170, a ferroelectric layer 240 is formed on the plurality of exposed portions of channel sidewall 234. The ferroelectric layer 240 can include a ferroelectric material 241 and an optional thin interfacial layer (not shown in the figures). The interfacial layer can be silicon oxide and/or nitride or similar materials. A ferroelectric layer 240 can include one or more layers of a ferroelectric material. An exemplary, non-limiting ferroelectric material 241 can be hafnium oxide. The ferroelectric material 241 can be doped with a doping element or can be undoped. Exemplary doping elements include Zr, Al, Ca, Ce, Dy, Er, Gd, Ge, La, N, Sc, Si, Sr, Sn and Y. The ferroelectric material 241 can be deposited in a selective process or a non-selective process. FIG. 8A illustrates the ferroelectric layer 240 formed non-selectively. In a non-selective formation, the interfacial layer can be formed first and then the ferroelectric material can be deposited. One or both layers can be formed by atomic layer deposition (ALD) or chemical vapor deposition (CVD). As a result, the ferroelectric layer 240 forms on exposed portions of the channel sidewall 234 and on exposed insulator 220 surfaces (and/or covering dielectric 221) in the horizontal cavity 238 to result in “C” shape or a sideways “U” shape with the interfacial layer between the ferroelectric material 241 (not separately shown in FIG. 8A) and the channel sidewall 234 and between the ferroelectric material 241 and the insulator 220 of the channel opening 232. FIG. 8B illustrates a ferroelectric material 241 of the ferroelectric layer 240 formed selectively. In a selective process the ferroelectric material 241 has a rectangular shape along the channel sidewalls while lacking horizontal wings along the horizontal cavity 238. To achieve the FIG. 8B rectangular shaped ferroelectric material 241 a selective ALD, selective CVD or a selective epitaxial process can be used. In the rectangular shaped ferroelectric layer 240 structure of FIG. 8B, an interfacial layer can optionally be formed after the ferroelectric material is formed, by way of example and not by limitation, by oxidizing the ferroelectric material. Therefore, in such cases the interfacial layer can be, at least, between the ferroelectric material and the metal electrode 245. When using a selective epitaxial process, the ferroelectric material 241 can be lattice matched with the channel 235 material. Alternatively, an epitaxially formed ferroelectric material 241 can be mismatched with respect to the channel 235 material. A lattice mismatch between the epitaxially formed ferroelectric material 241 and the channel 235 material can provide the opportunity to use a large class of material or compositions of ferroelectric materials 241. An epitaxially formed ferroelectric material 241 of the ferroelectric layer 240 can provide enhanced orientation control of the ferroelectric layer.

After forming the desired ferroelectric layer 240 shape, in step 180, the horizontal cavities 238 and vertical cavities 237 (see FIG. 7) are filled by a metal electrode 245 resulting in an “L”-shaped contact when viewed in cross-section. The metal electrode 245 can be a conformal titanium nitride layer and a tungsten fill layer or any other suitable conductors filling both the horizontal cavity 238 and the vertical cavity 237.

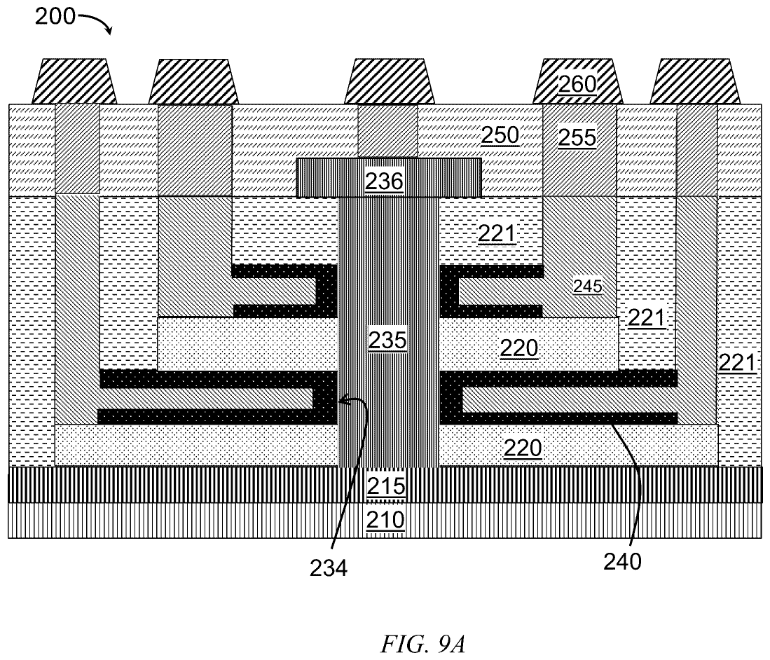

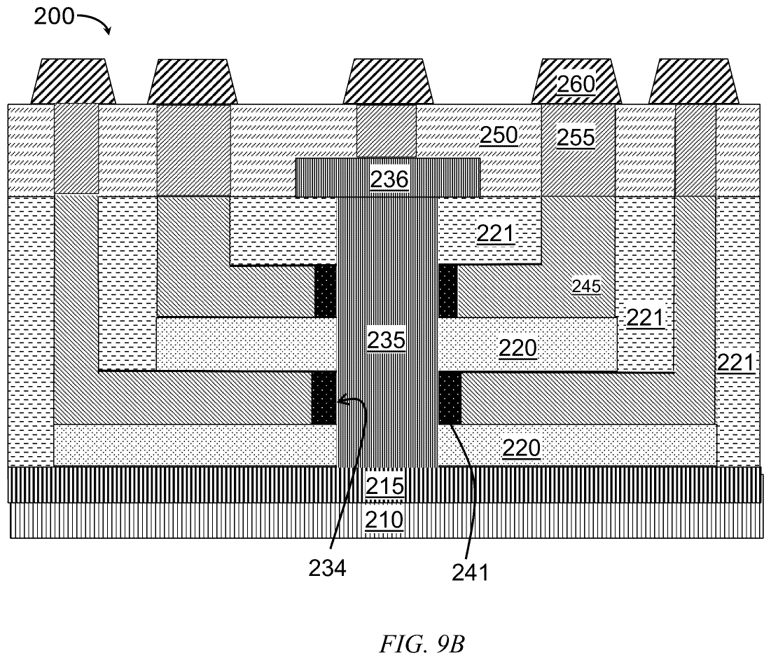

In step 190 and referring to FIGS. 9A and 9B, a contact dielectric 250 is deposited and lithographically patterned and etch to form contact trenches which expose the underlying metal electrodes 245 in the vertical cavity 237. A metal contact 255 is then formed in the contact trenches. Above the metal contact 255, interconnects 260 can be formed with accompanying dielectric (not shown). Contact dielectric 250 can be any suitable dielectric layer or combination of layers. Metal contact 255 can be a titanium nitride liner with tungsten fill or any suitable conductor(s). Interconnect 260 can include copper or any suitable conductor(s).

In summary, an aspect of a vertical ferroelectric field effect transistor includes a source 215, a drain 236, and a channel 235 in a channel opening 232 vertically connecting the source and the drain, the channel having channel sidewalls 234. An alternating stack of a plurality of insulator 220 layers and a plurality of metal electrodes 245 is on either side of the channel. A cover insulator over the alternating stack wherein the source is over and in contact with a top surface of the cover insulator and a ferroelectric layer 240 between and in contact with each of the plurality of metal electrodes 245 and a portion of the channel sidewalls 234.

Optionally, the channel 235 completely fills the channel opening 232, is a single crystalline semiconductor, is silicon, is a doped silicon, is silicon germanium, is a doped silicon germanium, or is a III-V compound.

Optionally, the ferroelectric layer 240 is lattice matched relative to the channel 235.

Optionally, the ferroelectric layer 240 is adjacent the channel 235 and has a rectangular shape with a first sidewall adjacent the channel 235, a second sidewall adjacent the metal electrode 245, a top sidewall adjacent a first of the plurality of insulator 220 layers and a bottom sidewall adjacent a second of the plurality of insulator 220 layers.

Optionally, the ferroelectric layer 240 includes an interfacial layer and a ferroelectric material. Optionally, the ferroelectric material includes hafnium oxide which can be undoped or doped with a doping elements. Doping elements can include one or more of Zr, Al, Ca, Ce, Dy, Er, Gd, Ge, La, N, Sc, Si, Sr, Sn and Y. 15.

Optionally, the ferroelectric layer 240 further includes a first horizontal portion and a second horizontal portion. Each of the first horizontal portion and the second horizontal portion is in contact with the metal electrode 245 and in contact with rectangular shape. The first horizontal portion adjacent the first of the plurality of insulator 220 layers and a second horizontal portion adjacent a second of the plurality of insulator layers.

In another aspect, a vertical ferroelectric field effect transistor includes a source 215, a drain 236, and a channel 235 in a channel opening 232 vertically between the source and the drain. The channel 235 comprises a single crystalline semiconductor filling the entire channel opening 232. An alternating stack of a plurality of insulator 220 layers and a plurality of metal electrodes 245 is on either side of the channel. A ferroelectric layer 240 between and in contact with each of the plurality of metal electrodes 245 and a portion of the channel sidewalls 234. The ferroelectric layer 240 has a rectangular shape and is lattice matched to the channel 235.

In a further aspect of the invention, a method 100 of manufacturing a vertical ferroelectric field effect transistor includes providing a semiconductor substrate 210 having a first doping, doping the substrate 210 to form a source 215 on the substrate, the source 215 having a second doping opposite the first doping, forming alternating layers of an insulator 220 and a sacrificial material 230 having a stepped profile end, forming a channel opening 232 through the alternating layers to expose the source 215, forming a single crystalline semiconductor channel 235 in the channel opening 232, forming a drain 236 on the channel 235 opposite the source 215; forming a vertical cavity 237 through the insulator 220 to expose a portion of the sacrificial material 230 at the stepped profile end, removing the sacrificial material 230 to form a horizontal cavity 238 in communication with the vertical cavity 237 and to expose a portion of the channel sidewall, forming a ferroelectric layer 240 having a rectangular shape on the channel sidewall, and forming a metal electrode 245 in the vertical cavity 237 and the horizontal cavity 238 and in contact with the ferroelectric layer 240.

Optionally, the ferroelectric layer 240 is lattice matched with the channel 235.

Optionally, the ferroelectric layer 240 includes a ferroelectric material 241 having a doping element. The doping element can bae one or more of Zr, Al, Ca, Ce, Dy, Er, Gd, Ge, La, N, Sc, Si, Sr, Sn and Y.

Optionally, the ferroelectric layer 240 further includes a first horizontal portion and a second horizontal portion. Each of the first horizontal portion and the second horizontal portion is in contact with the metal electrode 245 and in contact with the rectangular shape. The first horizontal portion is adjacent a first layer of the insulator 220 and a second horizontal portion is adjacent a second layer of the insulator 220.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A vertical ferroelectric field effect transistor comprising:
a source;
a drain;
a channel in a channel opening vertically connecting the source and the drain, the channel having channel sidewalls;
an alternating stack of a plurality of insulator layers and a plurality of metal electrodes on either side of the channel;
a cover insulator over the alternating stack wherein the source is over and in contact with a top surface of the cover insulator; and
a ferroelectric layer between and in contact with each of the plurality of metal electrodes and a portion of the channel sidewalls.

2. The vertical ferroelectric field effect transistor of claim 1 wherein the channel completely fills the channel opening.

3. The vertical ferroelectric field effect transistor of claim 1 wherein the channel is a single crystalline semiconductor.

4. The vertical ferroelectric field effect transistor of claim 3 wherein the channel is a silicon.

5. The vertical ferroelectric field effect transistor of claim 3 wherein the channel is a doped silicon.

6. The vertical ferroelectric field effect transistor of claim 3 wherein the channel is a silicon germanium.

7. The vertical ferroelectric field effect transistor of claim 3 wherein the channel is a doped silicon germanium.

8. The vertical ferroelectric field effect transistor of claim 3 wherein the channel is a III-V compound.

9. The vertical ferroelectric field effect transistor of claim 3 wherein the ferroelectric layer 240 is lattice matched relative to the channel.

10. The vertical ferroelectric field effect transistor of claim 3 wherein the ferroelectric layer is adjacent the channel and has a rectangular shape with a first sidewall adjacent the channel, a second sidewall adjacent the metal electrode, a top sidewall adjacent a first of the plurality of insulator layers and a bottom sidewall adjacent a second of the plurality of insulator layers.

11. The vertical ferroelectric field effect transistor of claim 1 wherein the ferroelectric layer 240 comprises an interfacial layer and a ferroelectric material.

12. The vertical ferroelectric field effect transistor of claim 11 wherein the ferroelectric material comprises hafnium oxide.

13. The vertical ferroelectric field effect transistor of claim 11 wherein the ferroelectric material comprises a doping element.

14. The vertical ferroelectric field effect transistor of claim 13 wherein the doping element comprises one or more of Zr, Al, Ca, Ce, Dy, Er, Gd, Ge, La, N, Sc, Si, Sr, Sn and Y.

15. The vertical ferroelectric field effect transistor of claim 11 wherein the ferroelectric material is undoped.

16. The vertical ferroelectric field effect transistor of claim 11 wherein the ferroelectric layer further comprises:
a first horizontal portion; and
a second horizontal portion;
wherein the each of the first horizontal portion and the second horizontal portion is in contact with the metal electrode and in contact with rectangular shape; and
wherein the first horizontal portion adjacent the first of the plurality of insulator layers and a second horizontal portion adjacent a second of the plurality of insulator layers.

17. A vertical ferroelectric field effect transistor comprising:
a source;
a drain;
a channel 235 in a channel opening vertically between the source and the drain, the channel having channel sidewalls wherein the channel comprises a single crystalline semiconductor filling the entire channel opening;
an alternating stack of a plurality of insulator layers and a plurality of metal electrodes on either side of the channel;
a ferroelectric layer between and in contact with each of the plurality of metal electrodes and a portion of the channel sidewalls;
wherein the ferroelectric layer has a rectangular shape;
wherein the ferroelectric layer is lattice matched to the channel.

18. A method of manufacturing a vertical ferroelectric field effect transistor, the method comprising:
providing a semiconductor substrate having a first doping;
doping the substrate to form a source on the substrate, the source having a second doping opposite the first doping;
forming alternating layers of an insulator and a sacrificial material having a stepped profile end;
forming a channel opening through the alternating layers to expose the source;
forming a channel in the channel opening, wherein the channel is a single crystalline semiconductor and wherein the channel has a plurality of channel sidewalls;
forming a drain on the channel opposite the source;
forming a vertical cavity through the insulator to expose a portion of the sacrificial material at the stepped profile end;
removing the sacrificial material to form a horizontal cavity in communication with the vertical cavity and to expose a portion of the channel sidewall;
forming a ferroelectric layer having a rectangular shape on the channel sidewall; and
forming a metal electrode in the vertical cavity and the horizontal cavity and in contact with the ferroelectric layer.

19. The method of claim 18,
wherein the ferroelectric layer is lattice matched with the channel;
wherein the ferroelectric layer comprises:
a ferroelectric material; and
a doping element;
wherein the doping element consists one or more of Zr, Al, Ca, Ce, Dy, Er, Gd, Ge, La, N, Sc, Si, Sr, Sn and Y.

20. The method of claim 19, wherein the ferroelectric layer further comprises
a first horizontal portion; and
a second horizontal portion;
wherein the each of the first horizontal portion and the second horizontal portion is in contact with the metal electrode and in contact with rectangular shape; and
wherein the first horizontal portion is adjacent a first layer of the insulator and a second horizontal portion is adjacent a second layer of the insulator.
